(19) United States
(12) Patent Application Publication
(10) Pub. No.: US 2015/0056754 A1
(43) Pub. Date: Feb. 26, 2015

(54) VACUUM MOLDING APPARATUS, SUBSTRATE PROCESSING SYSTEM HAVING THE SAME AND SUBSTRATE PROCESSING METHOD USING THE SAME

(71) Applicant: SAMSUNG ELECTRO-MECHANICS CO., LTD., Suwon-si (KR)

(72) Inventor: Seock Hyun Park, Suwon-si (KR)

(73) Assignee: SAMSUNG ELECTRO-MECHANICS CO., LTD., Suwon-si (KR)

(21) Appl. No.: 14/172,543

(22) Filed: Feb. 4, 2014

(30) Foreign Application Priority Data
Aug. 26, 2013 (KR) 10-2013-0101117

(51) Int. Cl. H01L 21/48; B23K 3/08; H01L 23/00; B23K 3/04

(52) U.S. Cl. CPC H01L 21/4803; B23K 3/04; B23K 3/08; H01L 21/4867; H01L 24/83; H01L 2924/151; H01L 2224/83815; H01L 2224/83986
USPC 438/125; 228/15.1; 425/388

(57) ABSTRACT

Disclosed herein is a substrate processing system, including: a feeding apparatus which feeds a substrate including a plurality of unit substrates into the substrate processing system; a vacuum molding apparatus which molds the substrate fed by the feeding apparatus; a paste printing apparatus which prints a solder paste on the substrate molded by the vacuum molding apparatus; a mounting apparatus which mounts an electronic device on the substrate on which the solder paste is printed; and a reflow apparatus which performs a reflow on the substrate on which the electronic device is mounted, wherein the vacuum molding apparatus includes a substrate molding control unit which controls the molding of the substrate. Therefore, the warpage (CAW) of the substrate is limitedly formed to improve the warpage (CAW) dispersion of the substrate, thereby improving bonding reliability and a mounting yield between the chip die and the bump of the substrate.

### CROSS REFERENCE TO RELATED APPLICATION

This application claims the benefit of Korean Patent Application No. 10-2013-0101117, filed on Aug. 26, 2013, entitled “Vacuum Molding Apparatus, Substrate Processing System Having The Same And Substrate Processing Method Using The Same”, which is hereby incorporated by reference in its entirety into this application.

### BACKGROUND OF THE INVENTION

1. Technical Field

The present invention relates to a vacuum molding apparatus, a substrate processing system having the same, and a substrate processing method using the same.

2. Description of the Related Art

As a demand for small, light, and multi-functional electronic devices is increased, integration of a substrate and electronic devices mounted thereon has been improved at a rapid speed. The substrate is gradually multilayered and thus wiring patterns formed on the substrate are also densified. Further, the integration of the electronic devices is also increased and a size thereof is miniaturized.

In particular, in the development of printed circuit board (PCB) industry, in various circuit forming techniques for improving characteristics of a product, the performance and function of a silicon die (Si-die) bonded to the printed circuit board is also increased depending on a bonding method, and thus the silicon die is believed to be developed as a core technology of the printed circuit board industry.

As a method of bonding the silicon die to the printed circuit board, a flip-chip technology has been used. Further, there is a controlled collapse chip connection (C4) method. Here, reliability of a controlled collapse chip connection wiring is an important factor for improving product reliability of chips on the substrate.

As such, a good connection between the chips and the printed circuit board may improve the product reliability. In this case, during each process of building-up the printed circuit board to have an interlayer structure, the printed circuit board is heated and thus may be expanded. The interlayer structure considerably affects warpage of a product due to a thickness, a shape, and the like of remaining copper.

The chip is mounted on the so formed printed circuit board by the flip-chip process. In the flip-chip process, there are many high-temperature working conditions of 150° C. or more, which may be a factor of increasing a coefficient of thermal expansion (CTE) of a material. The expanded printed circuit board is formed to have a convex and concave shape, and the like and the chip is mounted on the convex and concave shape. Herein, an area in which a chip die is connected to a bump of the printed circuit board is referred to as a controlled collapse chip connection area (C4 area).

A difference in a remaining copper rate of the controlled collapse chip connection area (C4 area) leads to a difference in a thickness of an insulating layer. A mis-match between the CTEs of a front side and a back side occurs due to the difference in the thickness. Consequently, the phenomenon causes a controlled collapse chip connection area warpage (C4 area warpage; CAW).

In other words, the mis-match between the CTEs of the printed circuit board and the chip may generate stresses during a thermal process, in which the stresses during the thermal process may consequently cause chip-level cracking and film delamination.

As described above, when a shape of the chip die and a shape of the bump (portion at which the die is connected to electrical characteristics) area of the printed circuit board are formed in an opposite direction to each other, a phenomenon that an assembly is not appropriately made may occur.

Therefore, the phenomenon may be a cause which reduces a mounting yield in a die assembly process.

In this case, as a method for improving a die assembly yield, the substrate is subjected to vacuum molding. However, when the shapes of the chip die and the printed circuit board differ from each other, a problem of a die mis-align occurs. To improve the problem, the substrate is subjected to the vacuum molding.

The advantage of the substrate forming method is that the bonding reliability and the mounting yield between the substrate and the chip die may be improved by molding the substrate matching the die shape.

However, both of the chip die and the printed circuit board do not have the same controlled collapse chip connection area warpage (C4 area warpage; CAW, hereinafter, referred to as “warpage”) value due to the thickness of copper (Cu) in the substrate, the shape of the circuit, the thickness of the insulating layer, and the like. In other words, even though the substrate is molded under the same pressure by the thickness of copper (Cu), the thickness and the shape of the insulating layer, and the like, the substrate may not be molded by the same warpage (CAW) value. The non-uniform warpage (CAW) values are a cause which reduces the substrate manufacturing yield and a cause which reduces the bonding reliability and the yield of the die area in the assembly process.

Therefore, in order to improve the bonding reliability between the chip die and the printed circuit board and the yield of the assembly, there is a need to improve the warpage (CAW) distribution, that is, the warpage dispersion.

### SUMMARY OF THE INVENTION

According to the preferred embodiment of the present invention, a substrate molding control unit is formed in a substrate processing system to control the warpage (CAW) of the substrate so as to improve the warpage (CAW) dispersion of the substrate, thereby improving the bonding reliability and the mounting yield between the chip die and the substrate. The present invention is completed based on the fact.

The present invention has been made in an effort to provide a substrate processing system with improved bonding reliability and mounting yield by controlling a warpage dispersion of a substrate.

Further, the present invention has been made in an effort to provide a vacuum molding apparatus capable of improving a warpage dispersion of a substrate and performing molding without a limitation of a shape, such as a concave and convex shape and a flat shape, by preparing a stopper in a substrate molding control unit and controlling a shape of the stopper to freely form a shape of warpage (CAW) of the substrate.

In addition, the present invention has been made in an effort to provide a substrate processing method capable of improving a substrate manufacturing yield of an assembly substrate by using a vacuum molding apparatus and a substrate processing system using the same.

According to a preferred embodiment of the present invention, there is provided a substrate processing system, including: a feeding apparatus which feeds a substrate including a plurality of unit substrates into the substrate processing system; a vacuum molding apparatus which molds the substrate fed by the feeding apparatus; a paste printing apparatus which prints a solder paste on the substrate molded by the vacuum molding apparatus; a mounting apparatus which mounts an electronic device on the substrate on which the solder paste is printed; and a reflow apparatus which performs a reflow on the substrate on which the electronic device is mounted, wherein the vacuum molding apparatus includes a substrate molding control unit which controls the molding of the substrate.

The substrate molding control unit may support a warpage of the substrate to control a warpage dispersion of the substrate.

The substrate molding control unit may perform a control so that the electronic device and the molded substrate have a warpage in the same direction.

The vacuum molding apparatus may include: a heater unit which applies heat to the substrate; and a vacuum apparatus unit which provides a vacuum force to the substrate to form the warpage of the substrate.

The heater unit may heat the substrate by block heating.

The vacuum apparatus unit may include an infrared heating unit disposed to correspond to the heater unit, and the substrate may be simultaneously applied with heat energy from the infrared heating unit and vacuum from the vacuum apparatus unit to warp the substrate in one direction.

The reflow apparatus may apply heat to the substrate and the solder paste to bond the substrate to the electronic device.

According to another preferred embodiment of the present invention, there is provided a vacuum molding apparatus, including: a heater unit which applies heat to a substrate; a vacuum apparatus unit which is disposed to correspond to the heater unit and includes vacuum areas, in which the substrate is vacuum sucked, to mold the substrate; and a substrate molding control unit which is disposed in the vacuum area to support a warpage of the substrate.

The vacuum apparatus unit may include a base mold and a bather rib which partitions an area of the base mold and supports the substrate, and the vacuum area is formed of cavities partitioned by the bather rib and includes the substrate molding control unit.

The substrate molding control unit may include: a stopper which is disposed in the vacuum area; and a vacuum nozzle which is formed to penetrate through the base mold and the stopper.

The stopper may include: a post which is formed in a height direction of the bather rib; and a landing part which is formed on an upper portion of the post and contacts/supports a warpage area of the substrate.

The post may be formed at a different height from the bather rib.

The stopper may be disposed in the vacuum areas, respectively and the post may be disposed at the same height.

A difference in a height between the post and the bather rib may range from 1 μm to 100 μm.

The stopper may be made of a metal material which includes any one of copper (Cu), nickel (Ni), aluminum (Al), iron (Fe), tungsten (W), zirconium (Zr), tin (Sn), titanium (Ti), and an alloy thereof.

An upper portion of the bather rib may support the substrate.

According to still another preferred embodiment of the present invention, there is provided a substrate processing method, including: feeding a substrate into a substrate processing system which mounts an electronic device on the substrate and collects a unit substrate; performing molding on the substrate; controlling a warpage of the substrate to control a warpage dispersion of the substrate; printing a solder paste on the substrate; mounting the electronic device on an upper portion of the substrate; and performing a reflow on the substrate.

In the performing of the molding on the substrate, the substrate may be heated at a moldable temperature to be vacuum sucked.

In the controlling of the warpage of the substrate to control a warpage dispersion of the substrate, the warpage of the molded substrate may be supported to control a warped degree of the substrate.

In the mounting of the electronic device, the electronic device may be mounted on the solder paste.

In the performing of the reflow, the substrate may be bonded to the electronic device by applying heat to the substrate and the solder paste.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified diagram illustrating a substrate processing system according to a preferred embodiment of the present invention;

FIG. 2A is a diagram illustrating a shape of a substrate and a chip which is formed by a substrate system according to Example 1 of the present invention and FIG. 2B is a diagram illustrating a shape of a substrate and a chip according to Comparative Example 1 of the present invention;

FIG. 3 is a cross-sectional view of a vacuum molding apparatus according to a detailed example of the present invention;

FIG. 4 is a plan view of a vacuum apparatus according to the detailed example of the present invention;

FIG. 5 is an enlarged view of the part A of FIG. 4;

FIG. 6 is a cross-sectional view taken along the line I-I′ of FIG. 5;

FIGS. 7A to 7C each are diagrams illustrating Example 2, Example 3, and Comparative Example 2 of the substrate which is molded by the vacuum molding apparatus according to the preferred embodiment of the present invention; and

FIG. 8 is a flow chart illustrating a substrate processing method according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

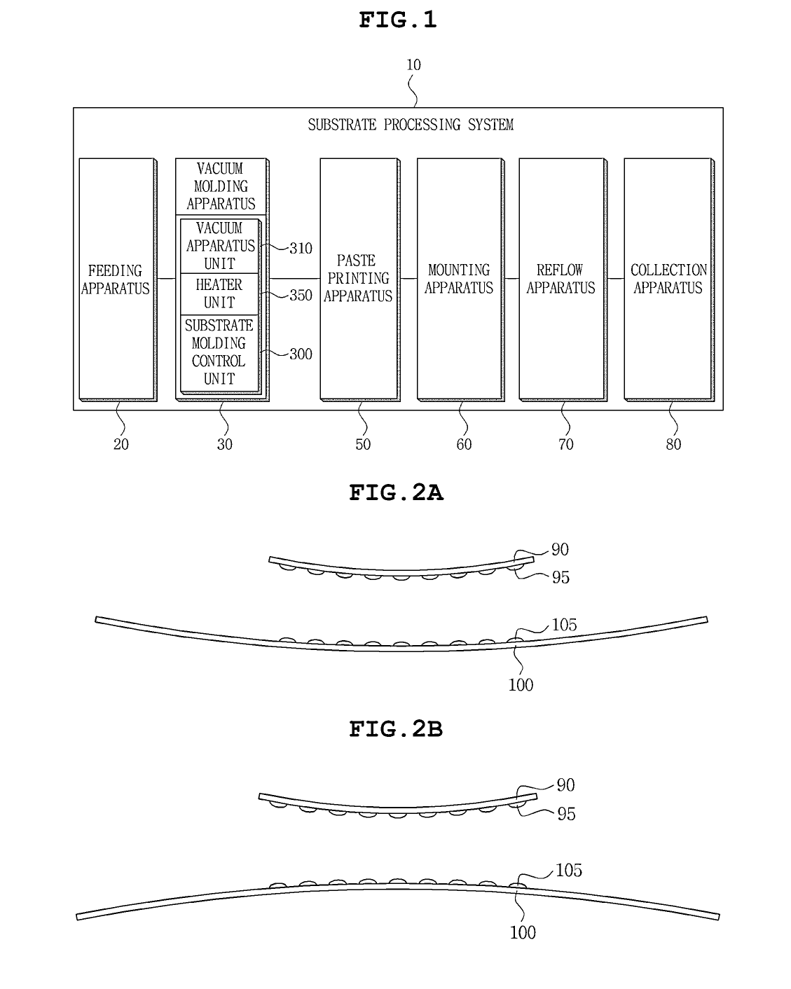

FIG. 1 is an exemplified diagram illustrating a substrate processing system according to a preferred embodiment of the present invention. FIG. 2A is a diagram illustrating a shape of a substrate and a chip which is formed by a substrate system according to Example 1 of the present invention and FIG. 2B is a diagram illustrating a shape of a substrate and a chip according to Comparative Example 1 of the present invention.

Referring to FIG. 1, a substrate processing system 10 may include a feeding apparatus 20, a vacuum molding apparatus 30 including a substrate molding control unit 300, a paste printing apparatus 40, a mounting apparatus 60, a reflow apparatus 70, and a collection apparatus 80.

The feeding apparatus 20 may feed a substrate into the substrate processing system 10. For example, the feeding apparatus 20 may be a robot arm, a conveyor, a roller, and the like. However, a kind of the feeding apparatus 20 is not limited thereto and therefore any feeding apparatus which may transfer the substrate positioned at the outside into the substrate processing system 10. According to the detailed example of the present invention, the substrate may include a plurality of unit substrates. Herein, the unit substrate may be a typical printed circuit board.

The vacuum molding apparatus 30 may mold the substrate. To this end, the vacuum molding apparatus 30 includes a vacuum apparatus unit 310, a heater unit 350, a substrate molding control unit 300. Next, the substrate and the chip are mounted and the substrate or the chip is warped during the formation process, and thus any problem may occur in bonding the substrate and the chip to each other. Therefore, the chip and a bump of the substrate are molded to have the same directivity by using the vacuum molding apparatus 30 which molds the substrate, thereby facilitating the mounting between the chip and the substrate.

Describing in more detail with reference to FIGS. 2A and 2B, the substrate 100 may be warped by being heated during a build-up process. This makes a remaining copper rate of front side and a back side of the substrate 100 different, such that a content of an insulating material filling a conductive layer becomes different. The difference in the content of the insulating material may cause a difference in a coefficient of thermal expansion (CTE). In addition, the difference in the CTE at high temperature is further increased. Since a flip chip method performs an operation at high temperature, the warpage of the substrate 100 may be further deteriorated due to a contraction and expansion of the material.

The substrate 100 and the chip die 90 may be easily mounted only when the warpage direction of the substrate 100 is the same as a direction of a chip die 90. That is, as illustrated in FIG. 2A, an important matter in mounting the chip die 90 on the substrate 100 has a constant directivity of a shape between a bump 95 of the chip and a bump 105 of the substrate. However, as illustrated in FIG. 2B, when the bump 95 of the chip and the bump 105 of the substrate have an opposite directivity to each other, it is highly likely to cause cracks and delamination in mounting the bump, thereby causing a defect. Therefore, only when the bump 95 of the chip and the bump 105 of the substrate have the same directivity, a mounting yield and a bonding reliability may be improved during an assembly process.

As described above, the substrate 100 may be molded by being vacuum sucked using the vacuum apparatus unit 310 of the vacuum molding apparatus 30 so that the bump 95 of the chip and the bump 105 of the substrate have the same directivity.

Further, when the vacuum molding apparatus 30 molds the substrate 100 by vacuum sucking the substrate 100, the substrate 100 may be heated by the heater unit 350. Further, in the vacuum molding apparatus 30, the vacuum apparatus unit 310 may further include an infrared heating unit (not illustrated) and the substrate 100 is simultaneously applied with heat energy from the infrared heating unit and vibration from the vacuum apparatus unit 310, thereby warping the substrate 100 in one direction.

The heater unit 350 may heat the substrate by block heating. Therefore, the substrate 100 may be in an easily warped state by the heater unit 350. That is, hard polymer materials have hard property at low temperature but have soft property like rubber at high temperature. The substrate may be easily molded only when being vacuum-molded in a soft state at a glass transition temperature (TG) point or more. Heat treatment at the glass transition temperature or more may reduce a plastic deformation time of a material. As described above, the vacuum molding apparatus 30 vacuum sucks the substrate 100 while applying heat to the substrate 100, thereby warping the substrate in one direction. Further, the vacuum molding apparatus 30 includes the heater unit 350 and the infrared heating unit of the vacuum apparatus unit 310 to apply the heat energy to upper and lower portions of the substrate 100, thereby stably keeping the molding temperature.

As described above, the vacuum molding apparatus 30 according to the preferred embodiment of the present invention controls a temperature range, in which heat is applied, up to a temperature which may mold the substrate, thereby improving the warped degree of the substrate and the reliability of an area. In this case, an apparatus applying heat may heat the substrate 100 through a reflow apparatus which applies hot blast.

The substrate molding control unit 300 controls a warpage of a substrate to control a warpage dispersion of the substrate. The substrate is molded by the vacuum molding apparatus and the molded substrate is warped by vacuum. In this case, even in the same product, it is difficult to control the warped degree of the substrate for various reasons, such as the remaining copper rate, the heating temperature, a thickness of the insulator, and the shape of the insulator. That is, the warpage difference in the warpage of the substrate is increased, that is, the dispersion is increased, such that there are an area in which the mounting is better made even on the substrate and an area in which the mounting is not made on the substrate. This may cause the reduction in the mounting yield.

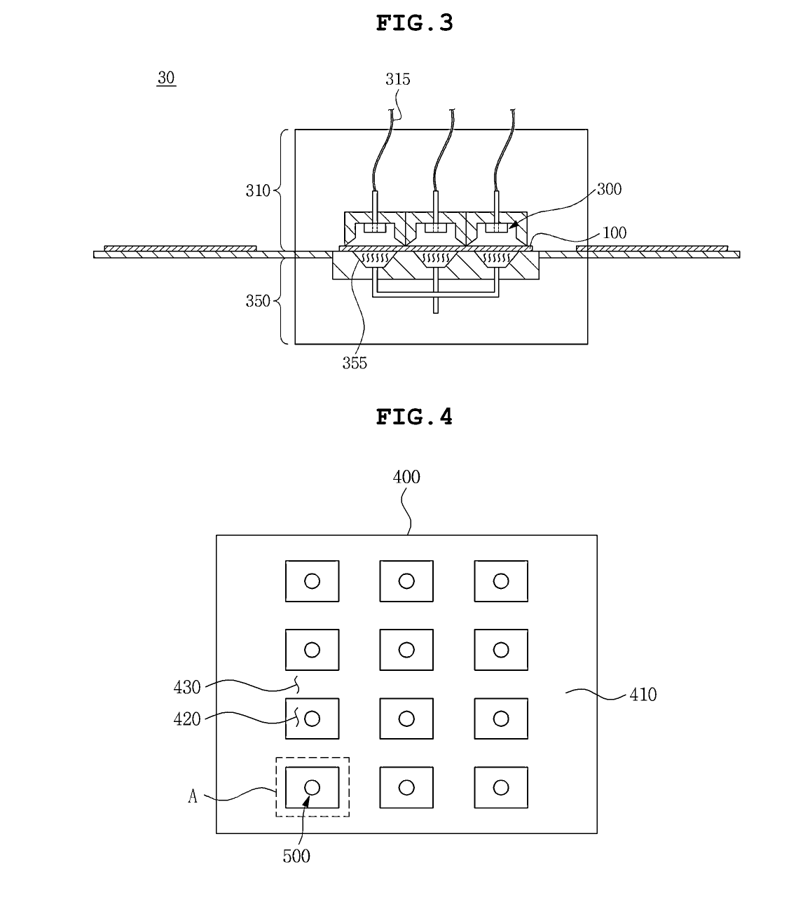

For this reason, the substrate molding control unit 300 may control the warpage dispersion of the substrate by controlling the warped degree of the substrate. The detailed description of the substrate molding control unit 300 will be described with reference to FIGS. 3 to 6.

The paste printing apparatus 50 may print a solder paste on the substrate 100. The paste printing apparatus 50 may dispose a mask, on which the opening is patterned, on the substrate 100 which is fed into the substrate processing system 10. Here, the opening may be disposed at a position corresponding to the bump to be formed later. The paste printing apparatus 50 may print the solder paste on the substrate through the opening of the mask by applying the solder paste on an upper portion of the mask.

The mounting apparatus 60 may mount electronic devices on an upper portion of the substrate 100. The mounting apparatus 60 may mount electronic devices in the area in which the solder paste is printed, in the upper portion of the substrate 100. Herein, the electronic devices may be, for example, the chip die 90.

The reflow apparatus 70 may perform a reflow on the substrate. The reflow apparatus 70 may heat the solder paste printed on the substrate to melt the substrate. For example, the reflow apparatus 70 may heat the solder paste by hot blast. As described above, the solder paste is melted by the reflow apparatus 70, such that an adhesion between the solder paste and the electronic devices may be increased.

The collection apparatus 80 may collect the substrate. The collection apparatus 80 may be molded to be warped in one direction by the vacuum molding apparatus 30 and collect the substrate including the unit substrate on which electronic devices are mounted.

As described above, the substrate processing system 10 uses the vacuum molding apparatus 30 which includes the heater unit 350, the vacuum apparatus unit 310, the substrate molding control unit 300 to control the warped degree of the substrate and matches the warpage directions of the chip die and the substrate to secure the easiness of the bonding, thereby improving the bonding reliability and the mounting yield.

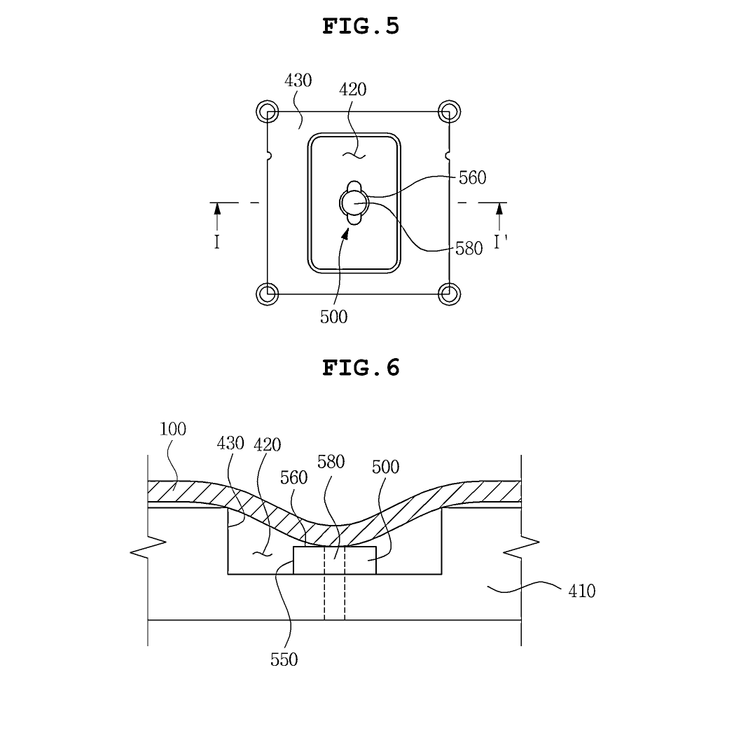

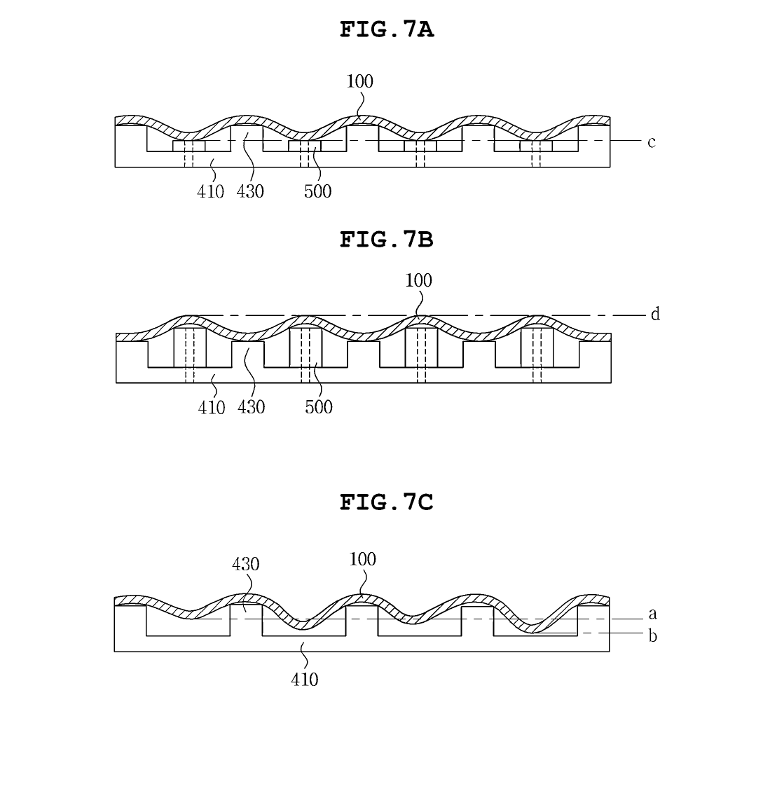

FIGS. 3 to 6 are exemplified diagrams illustrating the vacuum molding apparatus according to the detailed example of the present invention. FIG. 3 is a cross-sectional view of a vacuum molding apparatus according to a detailed example of the present invention, FIG. 4 is a plan view of a vacuum apparatus unit according to the detailed example of the present invention, FIG. 5 is an enlarged view of the part A of FIG. 4, and FIG. 6 is a cross-sectional view taken along the line I-I′ of FIG. 5. FIGS. 7A to 7C each are diagrams illustrating Example 2, Example 3, and Comparative Example 2 of the substrate which is molded by the vacuum molding apparatus according to the preferred embodiment of the present invention.

Referring to FIG. 3, the vacuum molding apparatus 30 may include the heater unit 350 formed on the front side, having the substrate 100 disposed therebetween, the vacuum apparatus unit 310 formed on the back side, and the substrate molding control unit 300.

The heater unit 350 may be formed on an upper portion or a lower portion of the vacuum molding apparatus 30. Describing by way of example, the substrate 100 may be aligned on the heater unit 350. A heater 355 disposed on the heater unit 350 may apply heat to the substrate 100.

At least one heater 355 may be formed in the heater unit 350. The heater 355 may apply heat to each of the unit substrates which is formed on the substrate 100. The heater 355 may control a range in which heat is applied to the unit substrate. According to the preferred embodiment of the present invention, the heater 355 may be a hot blast apparatus. In this case, the heater 355 may include an injector and a hot blast nozzle.

The vacuum apparatus units 310 are formed on the upper and lower portions of the vacuum molding apparatus 30 and may be disposed at a position at which the vacuum apparatus unit 310 and the heater unit 350 may correspond to each other. The vacuum apparatus unit 310 may further include the infrared heating unit to stably keep a molding temperature. The vacuum apparatus unit 310 includes a vacuum apparatus 315 which molds the substrate 100 by vacuum sucking the substrate 100.

In this case, the substrate 100 may be in a heated state at the temperature at which the substrate 100 may be molded by the heater 355. At least one vacuum apparatus 315 may be provided. The vacuum apparatus 315 may vacuum suck each of the unit substrates which is formed on the substrate 100. When the unit substrate is vacuum sucked by the vacuum apparatus 315, the unit substrate may be molded to be warped in one direction.

The substrate molding control unit 300 may be formed in the vacuum apparatus unit 310. In detail, when the substrate 100 is molded by being disposed in the vacuum area of the vacuum apparatus unit 310, the substrate 100 may be formed to control the warped degree of the substrate 100. The detailed description of the substrate molding control unit 300 will be described in more detail with reference to FIGS. 4 to 6.

Referring to FIGS. 4 to 6, the vacuum apparatus unit 310 of the vacuum molding apparatus 30 is provided with a base mold 410 and barrier ribs 430 which partition the base mold 410. The barrier rib 430 may be formed to be integrated with the base mold 410. Further, the barrier rib 430 is formed in a vertical direction to a surface direction of the base mold 410 and an upper portion of the barrier rib 430 may be a surface which supports the substrate 100.

The barrier ribs 430 are disposed at a predetermined interval and the vacuum areas 420 which are formed of cavities formed between the barrier ribs 430 are formed. The vacuum areas 420 formed as the cavities may have a shape corresponding to the unit of the substrate. Therefore, a shape of the cavity may be determined depending on the disposition of the bather rib 430. That is, a shape of the vacuum region 420 is determined depending on the disposition of the bather rib 430. In other words, the shape of the bather rib 430 may be determined depending on a size of the unit substrate. Alternatively, the bather rib 430 may be disposed by being divided into ¼ of an overall size by using a quad method.

The substrate molding control unit 300 is disposed in the vacuum area 420. Describing in more detail the substrate molding control unit 300 with reference to FIGS. 5 and 6, the substrate molding control unit 300 includes a stopper 500.

Since the stopper 500 may be made of a material having a heat resistant property against heat applied to mold the substrate 100, any material may be used without being limited. For example, the stopper may be made of a metal material which includes any one of copper (Cu), nickel (Ni), aluminum (Al), iron (Fe), tungsten (W), zirconium (Zr), tin (Sn), titanium (Ti), and an alloy thereof.

In the drawing illustrating the detailed example of the present invention, the stopper 500 includes a cylindrical post 550 and a circular landing part 560 but the preferred embodiment of the present invention is not limited thereto. That is, the stopper 500 includes the post 550 and the landing part 560 which have various shapes and the configuration thereof may be made of various alloys including various metals.

The stopper 500 includes the post 550 which is formed at a predetermined height in the base mold 410 and the landing part 560 which is formed on the upper portion of the post 550 to support the substrate 100.

The landing part 560 may support a force warping the substrate by a vacuum force. The landing part 560 may seat an area, in which the substrate 100 is warped, by the vacuum force. Further, a width of the landing part 560 may be formed in consideration of a shape (size, shape, and the like) of the vacuum area 420 or a bending stress of the substrate 100.

Therefore, the landing part 560 supports the vacuum force, which further warps the seated substrate, to prevent the substrate 100 from being further warped, thereby controlling the warped degree of the substrate.

The post 550 may form a height of the stopper 500. The post 550 may be formed at a height which is different from the height of the barrier rib 430. For example, as illustrated in the drawing, the post 550 may be also formed to be smaller than the height of the barrier rib 430 and although not illustrated, may be formed to be larger than the height of the barrier rib 430.

The height of the post 550 may control the warpage dispersion of the substrate 100. In other words, the substrate 100 is supported to the upper portion of the barrier rib 430. Further, the substrate 100 is molded by the vacuum apparatus unit 310 and the warped degree of the substrate may be limited to a difference in a height between the barrier rib 430 and the post 550 by the molding. Therefore, the post 550 of the stopper 500 may control the warpage dispersion of the substrate 100.

Further, the height of the post 550 may be controlled by the substrate molding control unit 300. That is, the warpage dispersion of the substrate may be controlled by the substrate molding control unit 300. The shape of the warpage (CAW) of the substrate may be freely formed by controlling the shape of the post, such that the warpage dispersion of the substrate may be improved and the substrate may be molded without a limitation of a shape, such as a concave and convex shape, a flat shape.

For example, the difference in the height between the bather rib 430 and the post 550 may be kept at a range of 1 μm to 100 μm. In more detail, the difference may be kept at a range of 10 μm to 40 μm. When the difference in the height between the barrier rib 430 and the post 550 has a range larger than that of 10 μm to 40 μm, the warpage dispersion of the substrate is formed to be large, such that it may be difficult to mount the chip die on the substrate 100.

Meanwhile, the substrate molding control unit 300 is provided with a vacuum nozzle 580 which is formed to penetrate through the stopper 500 from a bottom surface of the base mold 410. The vacuum nozzle 580 forms a hole in the landing part 560 of the stopper 500 to form vacuum in the vacuum area 420, such that the substrate 100 is pulled to the landing part 560, thereby molding the substrate 100. As such, the substrate 100 is pulled to the vacuum nozzle 580 and thus the substrate 100 is supported to the stopper 500. In this case, the substrate 100 is supported by contacting the landing part 560 of the stopper 500. Further, the substrate 100 may control the warpage dispersion of the substrate 100 by the post 550.

Referring to FIGS. 7A to 7C, as Example 2, as illustrated in FIG. 7A, the vacuum molding apparatus 30 including the stopper 500 may improve or constantly form the warped degree of the substrate, that is, the warpage dispersion of the substrate. Further, as Example 3, as illustrated in FIG. 7B, the height of the stopper is formed to be larger than that of the barrier rib. In this case, the landing part supports/fixes the substrate by vacuum and the heater unit applies the heat energy to warp the substrate toward the upper portion of the bather rib.

As such, the substrate is seated/supported to the stopper or the barrier rib by the vacuum force of the vacuum molding apparatus, thereby improving the warpage dispersions c and d of the substrate.

As Comparative Example 2, as illustrated in FIG. 7C, it can be appreciated that the vacuum molding apparatus 30 without the stopper 500 increases the warped degree of the substrate to make the warpage dispersion large. That is, an interval between a and b is increased, which indicates that the warpage dispersion of the substrate is formed to be large. Therefore, in mounting the chip die on the substrate later, the bonding reliability and the mounting yield may be reduced.

As described above, in molding the substrate 100, the post 550 of the stopper 500 controls the warpage of the substrate to control the warpage dispersion of the substrate. Therefore, the vacuum molding apparatus 30 including the substrate molding control unit 300 according to the preferred embodiment of the present invention controls the warped degree of the substrate, thereby improving the bonding reliability and the mounting yield at the time of mounting the chip die on the substrate 100.

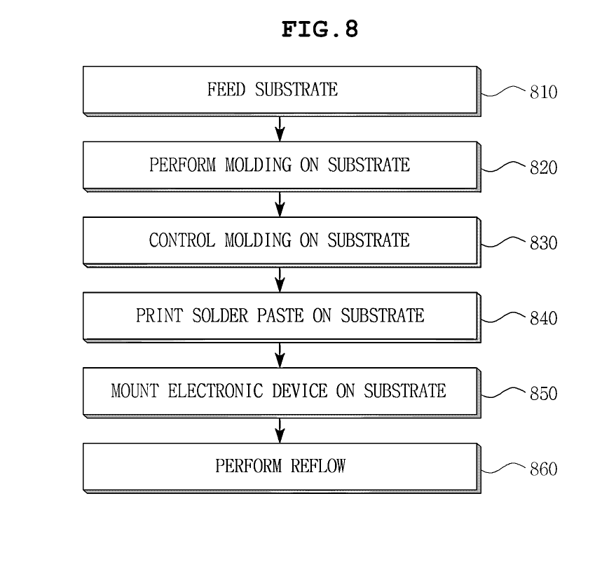

FIG. 8 is a flow chart illustrating a substrate processing method according to a preferred embodiment of the present invention. Herein, in order to avoid the overlapping description, the substrate processing method will be described with reference to FIGS. 1 to 6.

Referring to FIG. 8, first, the substrate 100 may be fed into the substrate processing system 10 (S810). Herein, the substrate processing system 10 may be a system which mounts electronic devices on the upper portion of the substrate 100 and collects the substrate. The detailed configuration of the substrate processing system will be described with reference to FIG. 1. The substrate may be fed into substrate processing system 10 by a feeding apparatus. Herein, the feeding apparatus may be a robot aim, a conveyor, a roller, and the like.

Next, the substrate processing system 10 may mold the substrate (S820). The molding of the substrate 100 may be performed by the vacuum molding apparatus 30. The vacuum molding apparatus 30 may perform the molding by vacuum sucking the substrate 100 in the state in which heat is applied to the substrate 100. The substrate moving to the vacuum molding apparatus 30 may be in a state illustrated in FIG. 7A. Referring to FIG. 7A, the substrate 100 may include a plurality of unit substrates. The substrate 100 may be warped in a direction of the vacuum area 420 by the heater unit 350 and the vacuum apparatus unit 310 of the vacuum molding apparatus 30.

Herein, the heater unit of the vacuum molding apparatus 30 provides the heat energy from the substrate and the vacuum apparatus unit provides the heat energy to the infrared heating unit, thereby stably keeping the substrate molding temperature. For example, the heater unit provides the heat energy of 200° C. to 220° C. to the substrate and the infrared heating unit provides the heat energy of 90° C. to 110° C., thereby stably keeping the substrate molding temperature.

Next, a process of controlling the molding of the substrate is performed (S830). Herein, the control of the molding of the substrate may be performed by the substrate molding control unit 300 which is included in the vacuum molding apparatus 30. The substrate molding control unit 300 included in the vacuum molding apparatus 30 may control the warpage dispersion of the substrate.

The substrate molding control unit 300 includes the stopper 500. The stopper 500 includes the post 550 which controls the height and the landing part 560 which supports/controls the force warping the substrate. Further, the substrate molding control unit 300 includes the vacuum nozzle 580 which is formed to penetrate through the stopper 500 and the base mold 410 to control the warpage of the substrate. Therefore, the warpage dispersion of the substrate may vary depending on the change in the height of the stopper 500.

For example, the difference in the height between the barrier rib 430 and the post 550 may range from 1 μm to 100 μm and when the difference in the height exceeds or less than the range, the warped degree of the substrate is reduced, such that the it may be difficult to bond the chip die and the substrate in the mounting process to be performed later.

When the vacuum molding apparatus 30 applies heat enough to mold the substrate 100, the vacuum molding apparatus 30 vacuum sucks the substrate 100 to mold the substrate 100 so that the unit substrate warped downward is warped upward as illustrated in FIG. 7A. The molding of the substrate is performed to facilitate the mounting while matching the directivity of the chip die. For example, the substrate may be warped in any direction due to the difference in a copper density between the upper and lower portions during the process of building-up the substrate. Herein, the substrate is molded by the vacuum molding apparatus, such that the warpage direction of the substrate may be the same as the warpage direction of the chip. The chip die mounted on the substrate may be, for example, an inductor as electronic components.

Next, the substrate processing system may print the solder paste on the substrate (S840). The solder paste may be printed by the paste printing apparatus. The paste printing apparatus may dispose the mask, on which the opening is patterned, on the upper portion of the substrate. Here, the opening may be disposed at a position corresponding to the bump to be formed later. The paste printing apparatus 50 may print the solder paste on the substrate through the opening of the mask by applying the solder paste on the upper portion of the mask.

Next, the substrate processing system may mount electronic devices on the upper portion of the substrate (S850). The mounting of the electronic devices may be performed by the mounting apparatus. The mounting apparatus may mount electronic devices in the area in which the solder paste is printed, in the upper portion of the substrate 100.

Next, the substrate processing system may perform the reflow (S860). The reflow may be performed by the reflow apparatus. The reflow apparatus may heat the solder paste printed on the substrate to melt the substrate. For example, the reflow apparatus may heat the solder paste using the hot blast, but the preferred embodiment of the present invention is not limited thereto. The reflow apparatus may use the hot blast as well as any thermal transfer medium which may melt the solder paste. As described above, the solder paste is melted by the reflow apparatus, such that the adhesion with the electronic device mounted on the upper portion of the solder paste may be increased.

The substrate processing method according to the preferred embodiments of the present invention may improve the bonding reliability and the mounting yield between the chip die and the bump of the substrate by improving the warpage (CAW) dispersion of the substrate by limitedly forming the warpage (CAW) of the substrate using the substrate molding control unit.

According to the vacuum molding apparatus, the substrate processing system, and the substrate processing method using the same according to the preferred embodiments of the present invention, it is possible to improve the bonding reliability and the mounting yield between the chip die and the bump of the substrate by improving the warpage (CAW) dispersion of the substrate by limitedly forming the warpage (CAW) of the substrate.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A substrate processing system, comprising:
a feeding apparatus which feeds a substrate including a plurality of unit substrates into the substrate processing system;
a vacuum molding apparatus which molds the substrate fed by the feeding apparatus;
a paste printing apparatus which prints a solder paste on the substrate molded by the vacuum molding apparatus;
a mounting apparatus which mounts an electronic device on the substrate on which the solder paste is printed; and
a reflow apparatus which performs a reflow on the substrate on which the electronic device is mounted,
wherein the vacuum molding apparatus includes a substrate molding control unit which controls the molding of the substrate.

2. The substrate processing system as set forth in claim 1, wherein the substrate molding control unit supports a warpage of the substrate to control a warpage dispersion of the substrate.

3. The substrate processing system as set forth in claim 1, wherein the substrate molding control unit performs a control so that the electronic device and the molded substrate have a warpage in the same direction.

4. The substrate processing system as set forth in claim 1, wherein the vacuum molding apparatus includes:
a heater unit which applies heat to the substrate; and
a vacuum apparatus unit which provides a vacuum force to the substrate to form the warpage of the substrate.

5. The substrate processing system as set forth in claim 4, wherein the heater unit heats the substrate by block heating.

6. The substrate processing system as set forth in claim 4, wherein the vacuum apparatus unit includes an infrared heating unit disposed to correspond to the heater unit, and
the substrate is simultaneously applied with heat energy from the infrared heating unit and vacuum from the vacuum apparatus unit to warp the substrate in one direction.

7. The substrate processing system as set forth in claim 1, wherein the reflow apparatus applies heat to the substrate and the solder paste to bond the substrate to the electronic device.

8. A vacuum molding apparatus, comprising:
a heater unit which applies heat to a substrate;
a vacuum apparatus unit which is disposed to correspond to the heater unit and includes vacuum areas, in which the substrate is vacuum sucked, to mold the substrate; and
a substrate molding control unit which is disposed in the vacuum area to support a warpage of the substrate.

9. The vacuum molding apparatus as set forth in claim 8, wherein the vacuum apparatus unit includes:
a base mold; and
a bather rib which partitions an area of the base mold and supports the substrate, and
the vacuum area is formed of cavities partitioned by the barrier rib and includes the substrate molding control unit.

10. The vacuum molding apparatus as set forth in claim 9, wherein the substrate molding control unit includes:
a stopper which is disposed in the vacuum area; and
a vacuum nozzle which is formed to penetrate through the base mold and the stopper.

11. The vacuum molding apparatus as set forth in claim 10, wherein the stopper includes:
a post which is formed in a height direction of the barrier rib; and
a landing part which is formed on an upper portion of the post and contacts/supports a warpage area of the substrate.

12. The vacuum molding apparatus as set forth in claim 11, wherein the post is formed at a different height from the barrier rib.

13. The vacuum molding apparatus as set forth in claim 11, wherein the stopper is disposed in the vacuum areas, respectively and the post is disposed at the same height.

14. The vacuum molding apparatus as set forth in claim 11, wherein a difference in a height between the post and the bather rib ranges from 1 μm to 100 μm.

15. The vacuum molding apparatus as set forth in claim 10, wherein the stopper is made of a metal material which includes any one of copper (Cu), nickel (Ni), aluminum (Al), iron (Fe), tungsten (W), zirconium (Zr), tin (Sn), titanium (Ti), and an alloy thereof.

16. The vacuum molding apparatus as set forth in claim 10, wherein an upper portion of the bather rib supports the substrate.

17. A substrate processing method, comprising:
feeding a substrate into a substrate processing system which mounts an electronic device on the substrate and collects a unit substrate;
performing molding on the substrate;
controlling a warpage of the substrate to control a warpage dispersion of the substrate;
printing a solder paste on the substrate;
mounting the electronic device on an upper portion of the substrate; and
performing a reflow on the substrate.

18. The substrate processing method as set forth in claim 17, wherein in the performing of the molding on the substrate, the substrate is heated at a moldable temperature to be vacuum sucked.

19. The substrate processing method as set forth in claim 17, wherein in the controlling of the warpage of the substrate to control a warpage dispersion of the substrate, the warpage of the molded substrate is supported to control a warped degree of the substrate.

20. The substrate processing method as set forth in claim 17, wherein in the mounting of the electronic device, the electronic device is mounted on the solder paste.

21. The substrate processing method as set forth in claim 17, wherein in the performing of the reflow, the substrate is bonded to the electronic device by applying heat to the substrate and the solder paste.
